(19) United States
(12) Patent Application Publication
(10) Pub. No.: US 2006/0227640 A1
(43) Pub. Date: Oct. 12, 2006

(54) Sensing device with activation and sensing alert functions

(75) Inventors: Richard Dan Herschaft, Whitestone, NY (US); Akinlolu Oloruntosi Kumoluyi, Marietta, GA (US); Alain Charles Louis Briancon, Poolesville, MD (US); Steven Jeffrey Goldberg, Downingtown, PA (US); Peter Shaomin Wang, E. Setauket, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: InterDigital Technology Corporation, Wilmington, DE (US)

(21) Appl. No.: 11/286,099

(22) Filed: Nov. 23, 2005

Related U.S. Application Data
(60) Provisional application No. 60/633,527, filed on Dec. 6, 2004.

(51) Int. Cl. G11C 7/02

(52) U.S. Cl. 365/207

(57) ABSTRACT

A sensing apparatus having a sensing functionality controller and a method of detecting the sensing apparatus is disclosed. A signal generation unit embedded in the sensing apparatus operates in conjunction with the sensing functionality controller to support the sensing functionality of the sensing unit. The signal generation unit generates one or more sensing functionality support signals used to enhance content obtained by the sensing unit, (e.g., a flash for illuminating a sensed target such that content obtained by the sensing unit is not too dark, or a sound or light-based auto focus signal to make sure that the content is not out of focus). When the sensing functionality controller is activated, the same signal generation unit generates a detectable warning signal, (e.g., sound, light, radio wave), which indicates that the sensing functionality controller has been activated and/or the sensing unit is sensing.

### CROSS REFERENCE TO RELATED APPLICATION

This application claims the benefit of U.S. Provisional Patent Application No. 60/633,527 filed Dec. 6, 2004, which is incorporated by reference as if fully set forth.

### FIELD OF INVENTION

This present invention is related to a sensing devices which capture images and/or sound, such as optical sensing devices, (e.g., cameras), audible sensing devices, (e.g., sound recorders, telephones, personal data assistants (PDAs)), or both optical and audible sensing devices, (e.g., video recorders, videophones, camera phones). More particularly, the present invention is related to a sensing device which emits one or more detectable warning signals, (e.g., sound, light, radio signals), which indicate that a sensing functionality associated with the sensing device has been activated.

### BACKGROUND

Sensing functionality includes the capture of image and sound. Sensing device functionality has become miniaturized so that people may not be aware of the physical presence of a sensing device, such as cameras, microphones and speakerphones, which may be embedded in phones, PDAs, and watches. Sensing devices are also being integrated with other functionalities such as storage and transmission functionalities. This allows for the increased quantity and timeliness of sensed data. The surreptitious use of these sensing devices in designated restricted areas poses obvious security and privacy concerns.

The problem with this situation is that these devices may be used to locally record or relay sounds and/or images to another device, without proper authorization. The restriction of bringing these devices into certain areas is posted, or a search is made for their existence.

Emissions from electronic equipment may be used as a basis for detecting the existence and use of such equipment. By increasing the strength of these emissions and by giving them a more distinctive pattern, it would be possible to make it easier for a device at a distance to detect this signature. However, if the equipment is shielded in accordance with TEMPEST specifications, signals emitted from the equipment would be weak and their pattern can not be used to detect a particular type of device by using a detection device.

The physical dimensions of sensing devices have been shrinking and the basic functionality can be incorporated into devices with various forms so that the physical presence of a sensing device may not be detectable. Any existing indications that sensing is occurring, such as the light on a video camera can be covered and/or be imperceptible within the ambient conditions.

In conventional landline or wireless communication recording devices, a warning sound or message is sometimes emitted by telephone conversation recorders. This warning is either directly or indirectly mandated by Federal and State law.

There are systems which broadcast radio frequency beacons that tell devices, such as camera phones, to disable their camera function. For example, Iceberg Intellectual Properties Limited has implemented this approach, as disclosed in International Application No. WO 2004/089021 A2 by Patrick Snow entitled “Portable Digital Devices”.

Prior art sensing device detection schemes assume a degree of cooperation from the users of the recording devices. They also in general require that people do not attempt to defeat signaling mechanisms that disable the recording functions. The exception to this is the use of a camera function to detect signals that disable recording functions. This implementation however does not alert the target of the pictures of the occurrence of the recording.

The flash of a camera would be rather easy to detect, and utilize as an indication of picture taking. Unfortunately, flash usage does not always occur, and may be disabled. Given modern low level light detectors and the post processing capabilities of digital image software, this often is not an issue in regards to picture quality.

What is needed is a way to alert a person(s) or monitoring equipment to the existence or utilization of such equipment that does not rely on explicit signaling generated by the location protection/privacy system, (i.e., sensor/beacon system), but rather have elements of the physical process of recording, (e.g., core technology), be detectable through remote sensing. Simple modification of the transducers (audio, image/video) that deal with the core technology can be made more tamper proof.

The prior art uses the core recording functionality to generate an alert signal, such as a flash, sound or the like, to alert a target that it is being recorded. However, there is a possibility that these signals may not be strong or reliable enough to be received by the target. Furthermore, the target may not distinguish this signal from an “innocent” signal, or may be misguided by a false alarm.

It would be desirable to incorporate a warning mechanism in sensing devices to facilitate searching for the devices, identifying the devices or the users thereof, confiscating the devices and/or taking action against the users of the devices.

### SUMMARY

The present invention is related to a sensing apparatus having a sensing functionality controller and a method of detecting the sensing apparatus is disclosed. A signal generation unit embedded in the sensing apparatus operates in conjunction with the sensing functionality controller to support the sensing functionality of the sensing unit. The signal generation unit generates one or more sensing functionality support signals used to enhance content obtained by the sensing unit, (e.g., a flash for illuminating a sensed target such that content obtained by the sensing unit is not too dark, or a sound or light-based auto focus signal to make sure that the content is not out of focus). When the sensing functionality controller is activated, the same signal generation unit generates a detectable warning signal, (e.g., sound, light, radio wave), which indicates that the sensing functionality controller has been activated and/or the sensing unit is sensing.

### BRIEF DESCRIPTION OF THE DRAWINGS

A more detailed understanding of the invention may be had from the following description, given by way of example and to be understood in conjunction with the accompanying drawings wherein:

FIG. 1 shows a sensing device configured to emit a warning signal which may be detected by a human or a machine in accordance with the present invention;

FIG. 2 is a detailed block diagram of an exemplary sensing device which emits a warning signal in accordance with the present invention;

FIG. 3 is a detailed block diagram of an exemplary signal generation unit used in the sensing device of FIG. 2;

FIG. 4 illustrates how the location of an offending sensing device may be determined through the use of three monitoring units to measure warning signal time of arrival differences in accordance with one embodiment of the present invention; and

FIG. 5 illustrates how the location of an offending sensing device may be determined through the use of a multitude of monitoring devices, each of which covers a particular monitored area in accordance with another embodiment of the present invention.

### DETAILED DESCRIPTION OF THE PREFERRED EMBODIMENTS

The present invention counteracts the surreptitious aspect of sensing devices by having the sensing devices emit a warning signal which indicates that a sensing function is being performed. A sensing device can include any device which records and/or transmits images and sound, or a device which gathers samples, records and/or transmits information relating to the presence of biochemical substances.

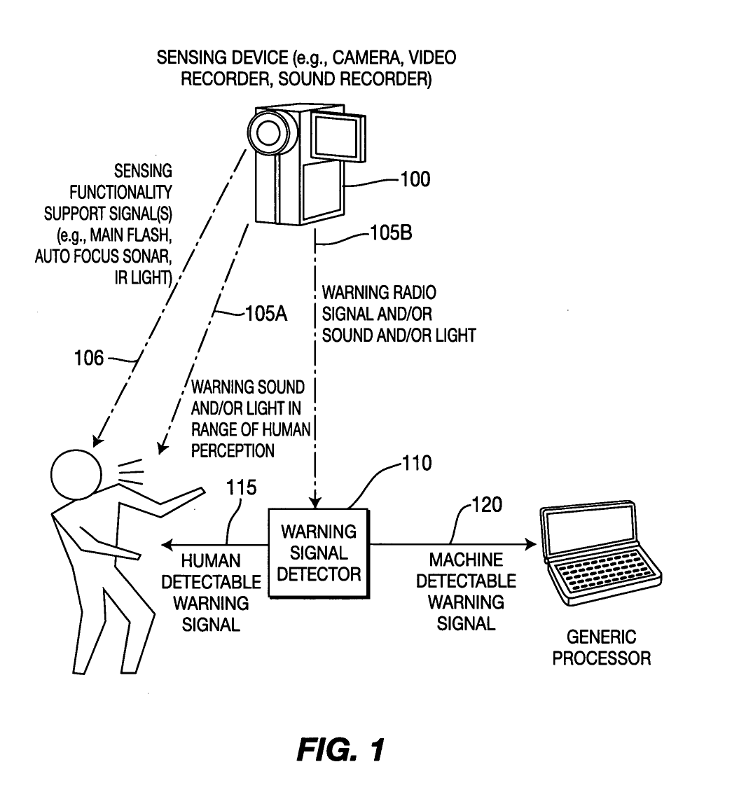

Referring to FIG. 1, a sensing device 100 can send out a warning signal(s) 105A, 105B when the sensing functionality is activated. The sensing functionality should ideally be made operational after the warning signal 105 has been emitted so that the parties in the area are able to react. After the sensing functionality is made operational, the warning signal 105 can be sent when the sensing is occurring or is anticipated to occur in the near future. For example, a “beep” may be emitted when camera functionality is “turned on” and then immediately before the camera is about to take a photo. For subsequent photos, the beep can be generated after taking into account the period of time since the previous beep. During a continuous form of sensing performed by a video or sound recorder, the warning beep can be sent out periodically during the image/sound capturing. The warning signal 105 may be considered interference for a sound sensing device. The sound sensing device will filter out this warning signal using signal processing.

A warning signal detector 110, (or a hearing aid as described below), can detect the warning signal 105B and then create a human detectable warning signal 115 or a machine detectable warning signal 120.

Still referring to FIG. 1, the sensing device 100 may also send out one or more sensing functionality support signals 106 which are used to enhance the sensing of a target and the generation of content associated with the target. For example, a main flash, (i.e., an optical/light signal), may be emitted by the sensing device 100 during its normal function in order to illuminate the area proximate to a target such that the content, (i.e., a picture or video), is not too dark. In another example, a sound navigation and ranging (SONAR) or infrared (IR) auto focus feature of the sensing device 100 may emit a SONAR signal or IR signal to determine the proper focus settings such that the content is not out of focus.

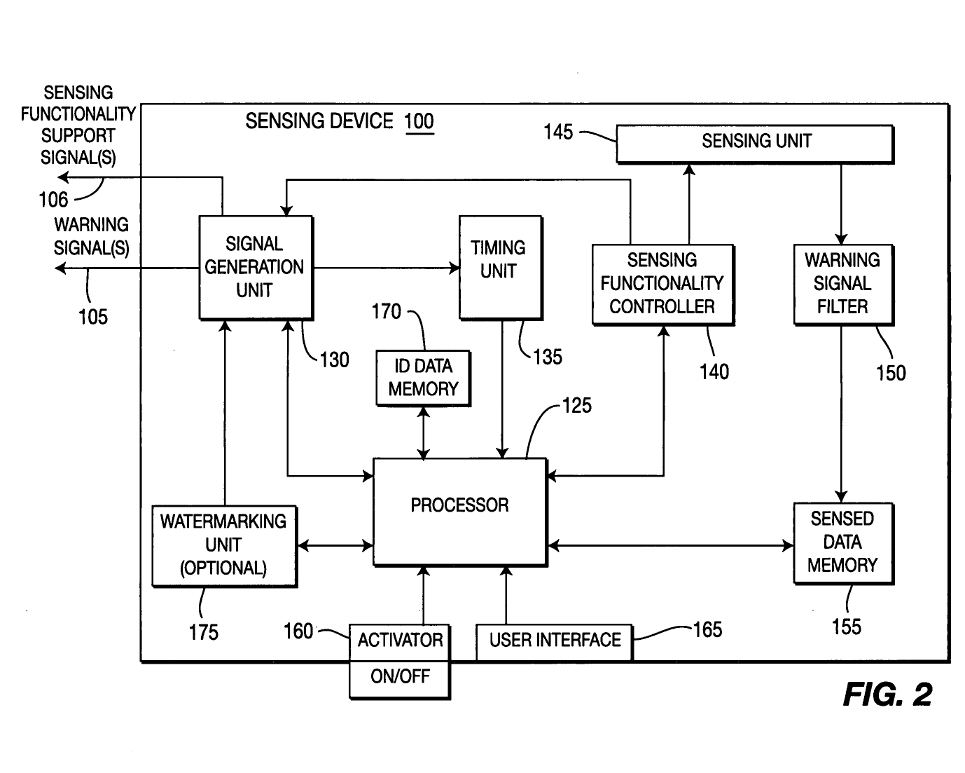

FIG. 2 is a block diagram of an exemplary sensing device 100 configured in accordance with the present invention. The sensing device 100 includes a processor 125, a signal generation unit 130, a timing unit 135, a sensing functionality controller 140, a sensing unit 145, a warning signal filter 150, a sensed data memory 155, an activator 160, a user interface 165, an identification (ID) data memory 170 and an optional watermarking unit 175.

Referring to FIG. 2, the sensing device 100 can send out a warning signal(s) 105 when the sensing functionality controller 140 is activated. When the processor 125 detects that the activator 160 has been turned on, the processor 125 activates the sensing functionality controller 140 and the signal generation unit 130. The sensing functionality controller 140 controls the sensing unit 145 such that it begins sensing, preferably after the signal generation unit 130 emits a warning signal 105 such that parties in the vicinity of the sensing device 100, or a target that is being sensed by the sensing device 100, are able to react. Depending on the type of the sensing device 100, the sensing unit 145 may be configured as a camera, (e.g., zoom lens), to take individual photos, as a sound recorder to record sounds on a continual basis, and/or as a video camera to record video. As described in detail above with respect to FIG. 1, the sensing device 100 is also configured to output one or more sensing functionality support signals to enhance content obtained by the sensing unit 145. After the sensing functionality is made operational, the warning signal 105 can be sent when the sensing is occurring or is anticipated to occur in the near future. For example, an audible warning signal 105 may be emitted from the signal generation unit 130 when the sensing functionality is “turned on” and then the warning signal may be emitted again immediately before the sensing unit 145 is about to take a photo. For subsequent photos, the audible warning signal 105 can be generated after taking into account the period of time since the previous warning signal 105, as determined by the timing unit 135. During a continuous form of sensing performed by a sensing device 100, such as a video or sound recorder, the warning signal 105 can be periodically emitted during the image/sound capturing, as determined by the timing unit 135.

The warning signal 105 may be considered as interference for a sound sensing device 100. The warning signal filter 150 will filter out this warning signal 105 using signal processing before images and/or sound captured by the sensing unit 145 are stored in the sensed data memory 155. The user interface 165 enables a user of the sensing device 100 to input settings and store identification information in the ID data memory 170. The optional watermarking unit 175 watermarks the warning signals 105 emitted by the sensing device 100.

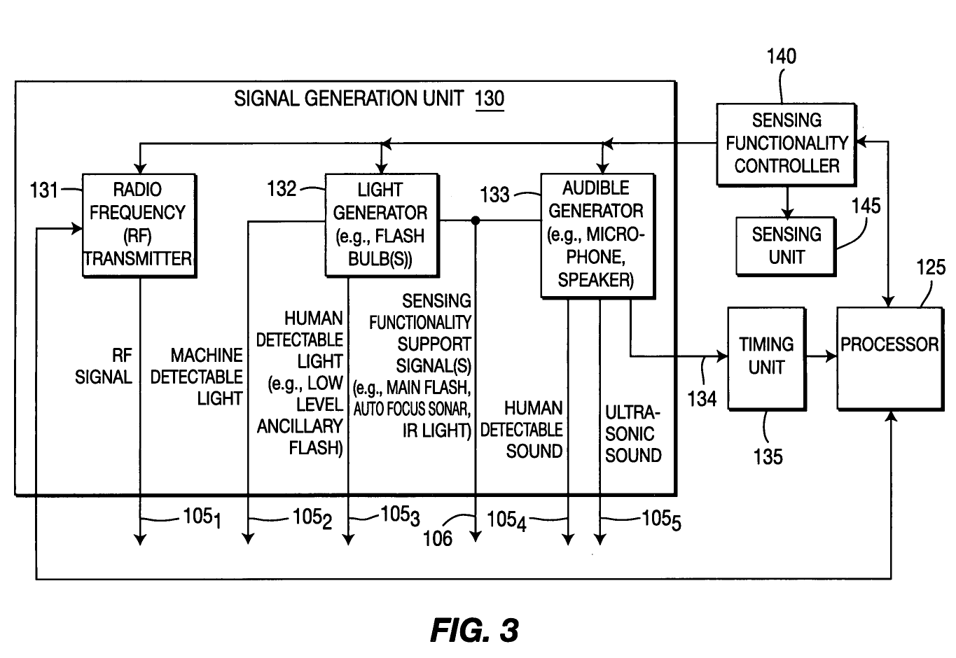

FIG. 3 is a detailed block diagram of an exemplary signal generation unit 130 used in the sensing device 100 of FIG. 2. As shown in FIGS. 2 and 3, the signal generation unit 130 may be controlled by the processor 125 and/or the sensing functionality controller 140 to emit a warning signal. Referring to FIG. 3, the signal generation unit 130 may be configured to include at least one of a radio frequency (RF) transmitter 131, a light generator 132, (e.g., flash bulb(s), “power on” light), and an audible generator 133, (e.g., a microphone or speaker), all of which are configured to emit warning signals 105. The RF transmitter 131 may emit an RF signal 105₁ to wirelessly inform a sensed target and/or a security guard about the activated sensing device 100. The light generator 132 may emit a machine detectable light signal 105₂, a human detectable light 1053, (e.g., a low level ancillary flash), and/or a sensing functionality support signal 106, (e.g., main flash, IR auto focus), which may be used to support sensing performed by the sensing unit 145, as described in detail above. The audible generator 133 may emit a human detectable sound 105₄ or an ultrasonic sound signal 105₅ and/or a sensing functionality support signal 106, (e.g., auto focus SONAR), which may also be used to support sensing performed by the sensing unit 145, as described in detail above. The specific configuration of the signal generation unit 130 is typically based on the type of the sensing unit 145 used to perform sensing.

The timing unit 135 is used in conjunction with the audible generator 133. The timer 135 is activated via a signal 134 which is output when the audible generator 133 emits either the human detectable sound signal 105₄ or the ultrasonic sound signal 105₅.

Aspects of the warning signal 105 should be proportional to the strength of the sensing functionality. The degree of strength can be represented by volume, pitch, or the time spacing of on and off periods. Volume may be the most suitable parameter since the volume will naturally decrease in proportion to the distance from the source of the sound. The sound can also indicate the class of a sensor device. The volume of the warning sound signal may need to be adjusted to remain noticeable within the ambient sound.

In one embodiment, it may be advantageous to time multiplex each sound in order to allow for sounds to remain distinct, since sounds may be emitted by other devices and other sources. Alternatively, a scheme similar to carrier sense multiple access/collision detection (CSMA/CD) can be applied to the transmission of sound signals. A sound sensor (not shown) may be incorporated within the sensing device 100 such that sound collisions may be detected.

Sound sensing devices include some form of microphone. If a warning sound signal 105 is emitted from the microphone, then any attempt to muffle the warning sound signal 105 will also muffle the sound being sensed. As stated with the emission of radio frequency (RF) signals below, a signal that is produced as an innate characteristic of a sensor is more difficult to disable. Substances can be made to vibrate via a number of mechanisms including pressure, light, heat, and sound. This vibration can create a sound with a particular pattern.

Interference caused by an audible warning signal 105 may be reduced or eliminated by placing the warning signal in a band outside of the range of human hearing, i.e., ultrasound. A specialized hearing aid may then be used to pick up the sound. It may be the case that in the future, hearing aids will become a common accessory. The term hearing aid usually refers to the reception of sound waves, whereas a speaker and headset usually refer to the conversion of electric signals into sound. From the perspective of the user, though, information is being conveyed in the form of sound and the term hearing aid will be used hereafter. A hearing aid can generally allow for hands free operation, including the frequently mentioned hands free driving. It can perform sound enhancement or sound cancellation. It can also pick up various forms of warning signals that involve a degree of personal preference. However, a signal such as a fire alarm signal would not be subject to someone's personal preferences.

The hearing aid can convert the out-of-band sound to an in-band sound including a spoken word representation of the signal. The sound signal can also be modulated with digital information which can be decoded by the hearing aid or by a receiver with some other form factor that has communication abilities. Thus a data modulated sound signal can act as a warning signal that is tailored to both the capabilities of humans and of machines. A hearing aid device can have the general functionality of converting data generated in various ways into sound, such as with the reception and conversion of the RF warning signal discussed below.

Light can also be used as a warning signal. A light signal may be emitted from the area of the lens of the camera, via the light generator 132 of the signal generation unit 130. Thus, any attempt to shield this warning signal will also result in covering the lens. Any distortion that this warning light will create will be filtered out of the image via signal processing. The light will be made noticeable but not annoying or dangerous to people. Therefore, a light sensor may be required in order to determine the adjustment to the intensity of the light warning signal such that a controlled relationship to ambient light is maintained. Similar to sound, the light may be modulated with data so that the signal is tailored to both the capabilities of humans and of machines. The light signal can also be emitted in a band out of the range of human perception.

An RF, digital or analog signal may be emitted to inform devices that monitor this warning signal. For example, the RF transmitter 131 in the signal generation unit 130 emits an RF signal 105₁. Irrespective of whether the RF signal 105₁ is digital or analog, the strength of the signal is proportional to the strength of the sensing. A digital signal may indicate various data items related to the sensing function, as stored in the ID data memory 170. These data items may include the type of sensor, the strength of sensor, the location of sensor and the sensing directional pattern. It is also possible that more personal/identification data may be revealed such as the serial number of the sensing device, the name of the sensing device, and contact information for the person responsible for the sensing device 100. These same data items may be used to modulate a sound or light warning signal generated by the signal generation unit 130. Some data items, (e.g., personal data), may only be revealed based on the sensing device 100 receiving an input, via the user interface 165, indicating the context or explicit instructions for operations. Such instructions may come from multiple parties. The combination of multiple instructions to form executable instructions will require a combining algorithm. This algorithm may require the use of artificial intelligence including the use of logic.

The information content of the RF signal may be contained in its analog characteristics. The amount of information contained may be less than that of a digital signal but may indicate the broad class of the sensing device 100 and may allow for enough uniqueness such that a particular device can be identified. The RF transmitter 131 in the signal generation unit 130 may be used to transmit the RF analog signal. This signal can generally be an analog signature but it may be possible to include digital information. By having the signature originate as an innate characteristic of the key component of a sensing device, makes it more difficult to disable the generation of the signature.

The warning signals 105 can be fully perceptible by humans and/or a monitor device can first receive the signal. The device which monitors the warning signal can be portable or stationary. It can be implanted, worn, or carried. It can convey the state of alarm to the user via various vibrations, various sounds (coded or language message), various light patterns, or can output a digital message to another device.

In one embodiment, the sensing device warning signals 105 may be coded by watermarks using the optional watermarking unit 175. These watermarks can represent data structures with sufficient information in them to uniquely identify the sensing device 100. The sensing device 100 is assigned watermarks based on the sensing functions of the sensing device 100. Each different type of sensing functionality has distinctive characteristics, (e.g., type of sensor, strength of sensor, location of sensor, sensing directional pattern, serial number of the sensing device, and the name, ID, and contact information for the person responsible for the sensing device, or the like). An administrative organization will have the responsibility to assign identifying information to each sensing functionality on each sensing device 100, as stored in the ID data memory 170.

Before the sensing function takes place, an appropriate watermarked warning signal may be emitted to provide sufficient time for the detecting device to react accordingly. Each detecting device has the capability to determine all known watermarks of sensing devices. The universe of sensing devices is either stored on the detecting device or special servers with adequate resources, (e.g., a computer processor unit (CPU), memory, cache, hard drive), to process look-up operations in a timely fashion. A search algorithm may be executed based on a number of schemes such as hashing, binary search and btree, or a combination thereof.

On the detecting device, there would be various converters that have different functions for solely transforming each watermark to an alert signal. An alert signal could be generated by a sound system, a vibrating system, a lighting system and/or just an interface that may be connected to other devices. Irrespective of the form of the alert system, it shall be customizable according to personal preferences. For example, a user may be able to choose a loud music selection when his/her picture is about to be taken and, if an unauthorized recording is about to take place, another kind of music could alert the user.

The function of warning that sensing is occurring or is about to occur is currently realized as a side effect of the existence or operation of the sensing device 100. Currently, sensing devices emit TEMPEST signals. A camera may send out a sound wave to perform auto-focusing. To enhance the amount of light on a subject, a flash may be used. The shutter of a camera can make a sound when light is admitted during the taking of a photo. The physical dimensions of a sensing device provide an indication of its presence. Video cameras have traditionally had a light visible to someone in front of the camera. The light informed the talent in front of multiple cameras which of the cameras is “live”. This feature has been carried over to camcorders.

In one embodiment of the present invention, a camera's flash device in a non-flash mode is used as the light generator 132 in the signal generation unit 130 to signal picture taking or camera existence via a sensing functionality support signal 106 that is generated, for example, by the main flash. Rather than generate a high lumens output as needed for illumination via the main flash signal 106, the light generator 132 can emit a low level light signal 105₃, in or out of the optical band, at specific repetition rates, and/or at specific frequencies to be detectable by suitably designed equipment, but not necessarily detectable by people or animals. The light generator 132 may include an ancillary flash bulb which may be used to generate the low level light signal 1053, such that it is triggered each time a picture is taken. Modulation could be superimposed to the flash using Ferroelectric light valves, modulated mirror arrays, piezoelectric shutters, Kerr cells, Pockels cells, Bragg cells, liquid crystals or the Digital Light Processing™ (DLP) technology from Texas Instruments.

Thus, various sound and electromagnetic signal generating mechanisms may be used a means to alert a sensor to the existence of a recording device. This alert may occur whenever the sensing device 100 device is turned on via the activator, or when the sensing device 100 passes through a portal and detects an “identify yourself” signal, or when it receives a broadcast “identify yourself” signal. The mechanisms may be activated periodically, as long they are powered up, or whenever sensing functionality is initiated. A warning signal detection device may be worn by a person, or be incorporated in an area detection device. The warning signal 105 is detected and appropriate alerting takes place. The alert may be to a specific person, to a centralized monitor station, relayed to a remote station or person, or its occurrence merely recorded. Any of these alerts may cause secondary functions to occur. For example, a security guard may be summoned, an audio signal may be generated, a picture may be taken of the area to identify the recorder's carrier, a watermark broadcast may be generated, and so on.

Another method is to use a microphone or speaker to generate a background predictable and modulated signal. The use of a modulated signal with a specific training-like sequence will increase the probability of detection at the location surveillance system. For example, coding techniques, such as the one used by NASA for deep space communication, may be used.

All licensed recording devices will emit electromagnetic or ultra sound signals to indicate the activation of a recording activity to alert the monitoring device from the venue or a person of such an occurrence. These signals will indicate the “electronic serial number” of the device for identifying the device and providing a signal for locating the position of the activated recording device.

In one embodiment, a monitoring device network may be provided to compute the position of the recording device based on the measured signal arrival time differences (in a large open space). The signal will be transmitted at certain frequency with a certain range at a certain modulation scheme to minimize interference to other devices. It transmits periodically to minimize multiple device emission collisions and to save device power. Frequency hopping and a randomly selected period between signals could be considered for multiple-device handling capacity. The offending device is either static or moving slowly, (e.g., less than or equal to 3 km/h). For short distance position locating, ultra sound may be better because it requires less timing accuracy requirement. This is only possible if an ultra sound wave could be used to carrying a device code.

In order for the relative timing measurements to be sufficiently accurate, the various detectors must interpret the same timing point or points within the signal. This can be accomplished by encoding modulation transitions or data strings within the transmissions that are uniquely identifiable.

In an area where recording is not allowed, a monitoring device will be installed for detecting the presence and the location of offending devices that have activated unauthorized. At least three (3) monitoring devices in a guarded area are networked for measurement data gathering and synchronized for timing accuracy. Once the reliable measurement data is available, (the device ID is distinguishable from three monitoring devices), the position of the offending device can be located using a reversed time difference on signal arrival (TDOA) position locating method.

In the following description, the principle of the position locating method is illustrated. The Ricean fading model is assumed (only electromagnetic), i.e., the signal path between the monitoring device and the offending device is line of sight (LOS) dominated.

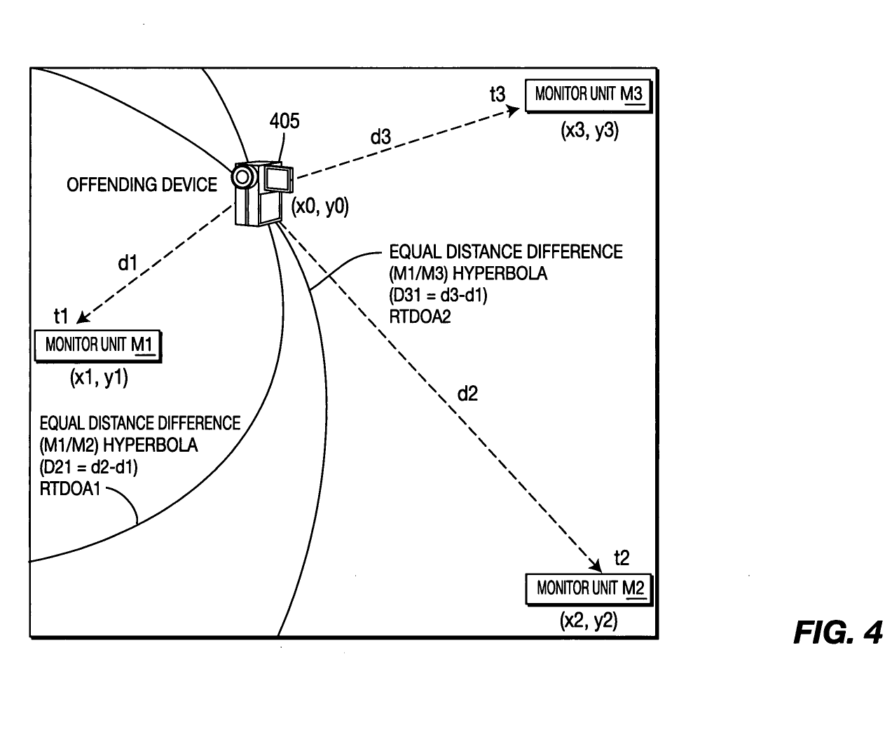

As shown in FIG. 4, an offending device 405 is located at the coordinates x0, y0. Three monitoring devices M1, M2 and M3 are used to generate at least two hyperbolas. The monitoring device M1 is located at coordinates x1, y1, the monitoring device M2 is located at coordinates at (x2, y2), and the monitoring device M3 is located at coordinates x3, y3. The monitoring devices M1, M2 and M3 are time synchronized to detect a signal emitted from the offending device 405 at times t1, t2 and t3.

At the time of the device-id reception, the offending device is in a position that is d1 distance from M1, d2 from M2 and d3 from M3. (Note d1, d2 and d3 are not measured, just a quantity used in the later equations).

The time differences between the arrival moments of two monitoring devices will then be (for simplicity only two shown) obtained at the monitoring network
T₂₁=|t2−t1|, and
T₃₁=|t3−t1|

The product of this time difference (Tᵢⱼ) and the speed of the transmitting media S, (e.g., electromagnetic wave 3×10⁸ meters, sound waves 3.4×10² meters in air), represent a distance (Dᵢⱼ=S×Tᵢⱼ). This distance defines the curve (a hyperbola) that at any point of the curve the differences between the distances to the two monitoring devices is a constant, or
Dᵢⱼ=S×Tᵢⱼ=|dⱼ−dᵢ|

For example in the above figure, the distance differences are determined as follows:
D₂₁=S×T₂₁ where T₂₁=|t2−t1|, and
D₃₁=S×T₃₁ where T₃₁=|t3−t1|.

Alternatively, the distance differences may be intuitively obtained as follows:
D₂₁=d2−d1| and D₃₁=d3−d1|.

Since all the monitoring devices and the offending device can be put in the same coordinate system, the following relationships may be established:
d1=√ (x₀−x₁)²+(y₀−y₁)²)};
d2=√ (x₀−x₂)²+(y₀−y₂)²)}; and
d3=√ (x₀−x₃)²+(y₀−y₃)²)}, where
D₂₁=d2−d1=\sqrt{(x₀−x₂)²+(y₀−y₂)²}−\sqrt{(x₀−x₁)²+(y₀−y₁)²}; and
D₃₁=d3−d1=\sqrt{(x₀−x₃)²+(y₀−y₃)²}−\sqrt{(x₀−x₁)²+(y₀−y₁)²}.

Since D₂₁ and D₃₁ are known quantities, and xᵢ and yᵢ, (where i=1, 2, 3), are also known quantities in the system, only x₀ and y₀ are the unknown coordinates of the offending device position to be solved.

Thus we have 2 unknowns and 2 equations (they are non-linear) for the computation of (x0, y0), the position of the offending device can be determined by carrying out the non-linear equations to linear computations, as is well known in the art.

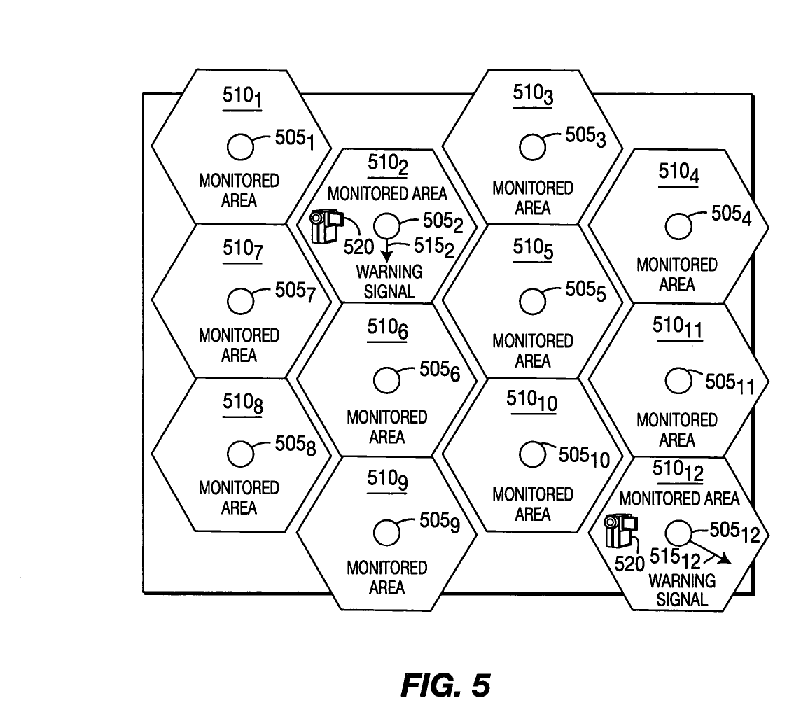

In another embodiment, a monitoring device grid net covering positions on sensed signal energy may be used, as shown in FIG. 5. In venues with convenient fixtures, such as theater hall seats, banquet hall tables or pillars, inexpensive monitoring devices 505₁-505₁₂ that only turn on to the special frequency for the expected warning signals with a received signal strength threshold set to a level that roughly covers the monitoring area with the size (the received energy is roughly in inverse proportion to the square of the distance) suitable for further action.

Each monitoring device 505₁-505₁₂ is installed to monitor a certain range of area 510₁-510₁₂. When the offending device 520 is activated, the nearest device 505₂, 505₁₂ senses the signal and alert the authority for appropriate actions by emitting respective warning signals 515₂ and 515₁₂.

According to the geography of the monitored area, the deployment of the monitoring device 505 and coverage grid may vary. The monitoring device 505 may also be more sophisticated to use the directional technology for pointing to the direction of the offending device 520.

Although the features and elements of the present invention are described in the preferred embodiments in particular combinations, each feature or element can be used alone without the other features and elements of the preferred embodiments or in various combinations with or without other features and elements of the present invention.

What is claimed is:

1. A method of detecting a sensing apparatus having a sensing functionality controller which controls sensing functionality of a sensing unit, the method comprising:
(a) embedding a signal generation unit in the sensing apparatus, the signal generation unit operating in conjunction with the sensing functionality controller to support the sensing functionality of the sensing unit;
(b) activating the sensing functionality controller;
(c) the signal generation unit generating a detectable warning signal which indicates that the sensing functionality controller has been activated;
(d) the signal generation unit generating a sensing functionality support signal used to support the sensing functionality of the sensing unit; and
(e) detecting the sensing apparatus based on the warning signal.

2. The method of claim 1 wherein the warning signal and the sensing functionality support signal are the same signal.

3. The method of claim 1 wherein the sensing unit is a sound sensing unit.

4. The method of claim 1 wherein the sensing unit is an image sensing unit.

5. The method of claim 1 wherein the sensing apparatus is a camera.

6. The method of claim 1 wherein the sensing apparatus is a video camera.

7. The method of claim 1 wherein the sensing unit is a biochemical sensing unit.

8. The method of claim 1 wherein the warning signal is an ultrasound signal.

9. The method of claim 1 wherein the sensing apparatus is a sound recorder, the method further comprising:
(f) the sensing unit detecting a plurality of different sounds emitted from different sources; and
(g) multiplexing each of the different sounds such that the different sounds are distinct from each other.

10. The method of claim 1 wherein the sensing apparatus is a sound recorder, the method further comprising:
(f) the sensing unit detecting a plurality of different sounds emitted from different sources; and
(g) detecting collisions among the different sounds.

11. The method of claim 1 wherein the sensing functionality support signal is a light signal generated by a low level ancillary flash bulb in the signal generation unit.

12. The method of claim 1 wherein the sensing functionality support signal is an audible signal generated by an audible generator in the signal generation unit to enhance content obtained by the sensing unit by supporting focusing of the content.

13. The method of claim 12 wherein the audible generator generates the warning signal.

14. The method of claim 1 wherein the sensing functionality support signal is a light signal generated by a primary flash device used to illuminate the area proximate to a target that the sensing device senses to generate a photograph.

15. A method of detecting a sensing apparatus having a sensing functionality, the method comprising:
(a) activating the sensing functionality;
(b) the sensing apparatus emitting at least one detectable warning signal which indicates that the sensing functionality has been activated; and
(c) locating the sensing apparatus based on the warning signal.

16. A method of detecting a sensing apparatus having a sensing functionality, the method comprising:
(a) activating the sensing functionality;
(b) the sensing apparatus emitting at least one detectable warning signal which indicates that the sensing functionality has been activated; and
(c) identifying a user of the sensing apparatus based on the warning signal.

17. A method of detecting a sensing apparatus having a sensing functionality, the method comprising:
(a) activating the sensing functionality;
(b) the sensing apparatus emitting at least one detectable warning signal which indicates that the sensing functionality has been activated; and
(c) identifying the sensing apparatus based on the warning signal.

18. A method of detecting a sensing apparatus having a sensing functionality, the method comprising:
(a) activating the sensing functionality;
(b) the sensing apparatus emitting at least one detectable warning signal which indicates that sensing is occurring or is going to occur in the immediate future; and
(c) locating the sensing apparatus based on the warning signal.

19. A method of detecting a sensing apparatus having a sensing functionality, the method comprising:
(a) activating the sensing functionality;
(b) the sensing apparatus emitting at least one detectable warning signal which indicates that sensing is occurring or is going to occur in the immediate future; and
(c) identifying a user of the sensing apparatus based on the warning signal.

20. A method of detecting a sensing apparatus having a sensing functionality, the method comprising:
(a) activating the sensing functionality;
(b) the sensing apparatus emitting at least one detectable warning signal which indicates that sensing is occurring or is going to occur in the immediate future; and
(c) identifying the sensing apparatus based on the warning signal.

21. A method of detecting a sensing apparatus having a sensing functionality, the method comprising:
(a) the sensing apparatus emitting a first warning signal after the sensing functionality is activated but sensing has not yet occurred;
(b) the sensing apparatus emitting a second warning signal when sensing is occurring or is going to occur in the immediate future;
(c) the sensing apparatus emitting additional warning signals on a periodic basis as long as the sensing continues to occur; and
(d) detecting at least one of the warning signals.

22. The method of claim 21 wherein the first, second and additional warning signals are audible signals.

23. The method of claim 21 wherein the first, second and additional warning signals are light signals.

24. The method of claim 21 wherein the first, second and additional warning signals are radio signals.

25. The method of claim 21 wherein the sensing apparatus is a video recorder.

26. The method of claim 21 wherein the sensing apparatus is a sound recorder.

27. The method of claim 22 wherein the sensing apparatus is a sound recorder, the method further comprising:
(e) the sound recorder filtering out the warning signals such that the warning signals are not recorded.

28. The method of claim 21 further comprising:
(e) watermarking at least one of the warning signals, the watermarking representing data structures with sufficient information which uniquely identifies the sensing apparatus.

29. The method of claim 21 further comprising:
(e) locating the position of the sensing apparatus.

30. The method of claim 21 further comprising:
(e) determining the user of the sensing apparatus.

31. The method of claim 21 further comprising:
(e) determining the identity of the sensing apparatus.

32. The method of claim 31 wherein step (e) further comprises:
(e1) using at least three monitoring units to measure warning signal time of arrival differences; and
(e2) generating at least two hyperbolas based on the time of arrival differences between warning signals received at the monitoring units, and distance differences between respective ones of the monitoring units and the sensing apparatus.

33. The method of claim 31 wherein step (e) comprises:
(e1) assigning a monitor unit to each of a plurality of monitored areas; and
(e2) a particular one of the monitor units emitting a warning signal when the sensing apparatus is detected as being located in the area monitored by the particular monitor unit.

34. A sensing apparatus comprising:
(a) a sensing unit having sensing functionality;
(b) a sensing functionality controller which controls the sensing unit;
(c) a sensing functionality activator; and
(d) a signal generation unit for emitting a first warning signal after the sensing functionality is activated by the activator but sensing by the sensing unit has not yet occurred, a second warning signal when sensing is occurring or is going to occur in the immediate future, and additional warning signals on a periodic basis as long as the sensing performed by the sensing unit continues to occur.

35. The sensing apparatus of claim 34 wherein the first, second and additional warning signals are audible signals.

36. The sensing apparatus of claim 34 wherein the first, second and additional warning signals are light signals.

37. The sensing apparatus of claim 34 wherein the first, second and additional warning signals are radio signals.

38. The sensing apparatus of claim 34 wherein the sensing apparatus is a video recorder.

39. The sensing apparatus of claim 34 wherein the sensing apparatus is a sound recorder.

40. The sensing apparatus of claim 35 further comprising:
(e) a warning signal filter for filtering out the warning signals such that the warning signals are not recorded.

41. The sensing apparatus of claim 34 further comprising:
(e) a watermarking unit for watermarking at least one of the warning signals, the watermarking representing data structures with sufficient information which uniquely identifies the sensing apparatus.

42. The sensing apparatus of claim 34 wherein the signal generation unit includes at least one of a radio frequency (RF) transmitter, a light generator and an audible generator for generating the warning signals.

43. The sensing apparatus of claim 42 further comprising:
(e) a timing unit, wherein the timing unit is activated when the signal generation unit emits a warning signal and another warning signal is emitted by the signal generation unit when the timing unit expires.

44. A sensing apparatus comprising:
(a) a sensing unit having sensing functionality;
(b) a sensing functionality controller which controls sensing functionality of the sensing unit;
(c) a signal generation unit which operates in conjunction with the sensing functionality controller to support the sensing functionality of the sensing unit, wherein when the sensing functionality controller is activated, the signal generation unit generates a detectable warning signal which indicates that the sensing functionality controller has been activated.

45. The sensing apparatus of claim 44 wherein the signal generation unit is configured to generate a sensing functionality support signal used to support the sensing functionality of the sensing unit.

46. The sensing apparatus of claim 45 wherein the warning signal and the sensing functionality support signal are the same signal.

47. The sensing apparatus of claim 44 wherein the sensing unit is a sound sensing unit.

48. The sensing apparatus of claim 44 wherein the sensing unit is an image sensing unit.

49. The sensing apparatus of claim 44 wherein the sensing apparatus is a camera.

50. The sensing apparatus of claim 44 wherein the sensing apparatus is a video camera.

51. The sensing apparatus of claim 44 wherein the sensing unit is a biochemical sensing unit.

52. The sensing apparatus of claim 44 wherein the warning signal is an ultrasonic sound signal.

53. The sensing apparatus of claim 44 wherein the sensing apparatus is a sound recorder which detects a plurality of different sounds emitted from different sources, and multiplexes each of the different sounds such that the different sounds are distinct from each other.

54. The sensing apparatus of claim 44 wherein the sensing apparatus is a sound recorder which detects a plurality of different sounds emitted from different sources, and detects collisions among the different sounds.

55. The sensing apparatus of claim 44 wherein the sensing functionality support signal is a light signal generated by a low level ancillary flash bulb in the signal generation unit.

56. The sensing apparatus of claim 44 wherein the sensing functionality support signal is an audible signal generated by an audible generator in the signal generation unit to enhance content obtained by the sensing unit by supporting focusing of the content.

57. The sensing apparatus of claim 44 wherein the sensing functionality support signal is a light signal generated by a primary flash device used to illuminate the area proximate to a target that the sensing device senses to generate a photograph.
